(19) United States
(12) Patent Application Publication
(10) Pub. No.: US 2005/0018526 A1
(43) Pub. Date: Jan. 27, 2005

(54) Phase-change memory device and manufacturing method thereof

(76) Inventor: Heon Lee, Seoul (KR)

Correspondence Address: WEBB ZIESENHEIM LOGSDON ORKIN & HANSON, P.C., 700 KOPPERS BUILDING, 436 SEVENTH AVENUE, PITTSBURGH, PA, 15219, US

(21) Appl. No.: 10/772,141

(22) Filed: Feb. 3, 2004

(30) Foreign Application Priority Data
Jul. 21, 2003 (KR) 10-2003-0049898
Sep. 5, 2003 (KR) 10-2003-0062050

(51) Int. Cl. G11C 8/02

(52) U.S. Cl. 365/232

(57) ABSTRACT

The present invention is to provide a phase change memory device having a new structure which can be easily manufactured by mass-production with a high yield rate, therefore, reducing the cost of process and providing reliable device characteristics, and a manufacturing method thereof. The present invention provides a phase-change memory device comprising: a lower dielectric layer; a lower electrode, at least a part of the lateral surface of the lower electrode being surrounded by the lower dielectric layer; a thin dielectric layer including a pore having smaller area than the top surface of the lower electrode, aligned to the top surface of the lower electrode and extending to the top surface of the lower electrode; and a phase-change resistor filling the pore and formed on the thin dielectric layer. In the proposed structure of the present invention, the pores or local damaged spots can provide a micro path of current and localize the phase-changing volume in the phase-change resistor. Thus, the phase-change memory device can be operated with very low power.

### BACKGROUND OF THE INVENTION

1. Field of the Invention

The present invention relates generally to a phase-change memory device and a manufacturing method thereof, and, more particularly, to a phase-change memory device having a new structure which can be easily manufactured by mass-production with a high yield rate, therefore, reducing the cost of process and providing reliable device characteristics.

2. Description of the Related Art

With expansion of mobile devices the demand for non-volatile memory devices are growing rapidly. Among the non-volatile memory devices which are widely used, the flash memory, the ferro-electric memory, the magnetic memory and the phase-change memory are leading the next generation of the non-volatile memory devices. Especially, the phase-change memory is being widely studied as it can resolve the flash memory's disadvantages including slow access speed, limited number of use times (about 10⁵˜10⁶ times) and high voltage requirement.

The phase-change memory is a memory device using phase-change materials which are, for example, chalcogenides including GST (Ge2Sb2Te5) and so on. The phase-change materials have reversible phase-change characteristics from/to crystalline phase and to/from amorphous phase. The resistivity of the phase-change material in the amorphous phase is much higher than in the crystalline phase. By using the change of the resistivity resulted from the change of phase, digital data can be stored and read.

FIG. 2 shows the digital data storage mechanism using the phase-change materials' crystallization and amorphization in a phase-change memory device. The amorphization of the phase-change material occurs when the phase-change material is heated above melting point by a high current pulse applied in a short time and quenched afterward. In addition, the crystallization is fulfilled by applying a low current pulse for a long time compared to the amorphization and annealing the phase-change material.

In FIG. 1, a conventional structure of the phase-change memory device is exemplified. The conventional structure is based on a general DRAM (Dynamic Random Access Memory) architecture. A phase-change resistor in the conventional phase-change memory device has a similar function with a capacitor that is used as a data storage part in the DRAM device. In the conventional phase-change memory device shown in FIG. 1, a memory cell consists of a FET 90 and a phase-change resistor 50 and stored digital data are represented by the resistance of the phase-change resistor 50 (High resistance or low resistance represents ‘0’ or ‘1’). The above mentioned memory cell structure is only one example employed in the phase-change memory devices and various modifications including a structure where a memory cell structure consists of a diode and a phase-change resistor have been published.

To embody the memory device structure exemplified in FIG. 1, device isolation structures such as trenches 10 on silicon substrate 5, a gate oxide film 15, word lines and gate electrodes 20, and source 12 and drain 14 are formed respectively. After that, a first inter-layer dielectric 23, contact holes 25 for bit lines, bit lines 30 and a second inter-layer dielectric 35, contact holes 40 for phase-change resistors are formed. Afterwards, the contact holes 40 are filled with electrode materials 45. Electrode materials can be tungsten, carbon, copper, aluminum, tungsten silicide, platinum, silver, gold, titanium, titanium nitride, doped poly silicon or other various conducting materials.

Then, the phase-change resistors 50 are formed on top of the electrodes 45. The phase-changing which occurs in the phase-change resistor 50, as shown in FIG. 2, mainly occurs around the area where the electrode 45 and the phase-change resistor 50 contacts. Therefore, if the contact area between the electrode 45 and the phase-change resistor 50 is reduced, it is possible to induce the phase-changing in the materials with a less electric power and a lower switching current, thus reducing power consumption of the device. In addition, switching with a higher speed is possible thus improving reliability of the device and the number of use times of the device can be increased.

Therefore, device structures and manufacturing methods for reducing contact area between the lower electrode and the phase-change resistor, lowering process difficulty, offering wide process margin and improving productivity have been widely studied and published.

FIG. 3 shows an example of conventional structures of the phase-change memory devices and a processing method published in the U.S. patent Publication No. 6,420,725. The phase-change memory device structure as shown in (f) is characterized in that sidewalls 142 are formed in lower contact holes 140 by deposition and etch-back of a dielectric layer, in order to reduce contact areas between lower electrodes 145 and phase-change resistors 150.

A processing method for embodying the above structure is as follows. As shown in (a), a dielectric layer 110 and contact holes 140 are formed on a substrate 110 and the contact holes 140 are filled with materials 190 to form diodes or electric contacts. After partially etching the materials 190, as shown in (b), a dielectric layer to establish sidewalls 142 is deposited. Then, sidewalls 142 are formed by an etch-back process as shown in (c) and material for forming lower electrodes 145 is deposited. After another etch-back process is fulfilled, lower electrodes 145 filling the open holes narrowed by the sidewalls 142 and being surrounded by the sidewalls 142 as shown in (d) are formed. On top of that, a phase-change material layer is deposited as shown in (e) and phase change resistors 150 and upper electrodes 155 are formed through appropriate patterning processes as shown in (f).

Using the conventional technology as explained above, reduced contact areas between the phase-change resistors 150 and the lower electrodes 145 can be achieved with a conventional lithographic technology. However, the additional processing steps including depositing and etching back the dielectric layer to form the sidewalls 142 are required. Therefore, total number of processing steps should be increased and the whole manufacturing process of the device becomes complicated. On the other hand, the above mentioned conventional technology can not be used for mass production because the holes 145 are too much narrowed by the sidewalls 142 and therefore it is very difficult to fill the holes 145 without voids using conventional metallic materials. In addition, although the holes 145 are narrowed by the sidewalls 142, entrances 149 of the holes 145 are not so much narrowed due to the tapered cross-sectional shape of the sidewalls 142. Because the entrances 149 are fully exposed during the etch-back process for forming the sidewalls 142, it becomes wider compared to the inside diameter of the holes 145 after the etch-back process is completed. Thus, the contact area between the phase-change resistors 150 and the lower electrode 145 cannot be decreased so much compared with the case without the sidewalls 142.

FIG. 4 shows another example of conventional phase-change memory device structure disclosed in the U.S. patent publication No. 6,337,266. The structure is characterized in that double spacers are formed in contact holes 240 to reduce contact area between lower electrodes 245 and phase-change resistors 250.

To embody the structure, a dielectric layer 235, holes 240, a first dielectric film 242 and a sacrificial layer 244 are formed as shown in (a) and (b). After that, the sacrificial layer 244 is etched without a mask and a primitive sidewall structure 244 is formed. Then, using the primitive sidewall structure as a mask, the first dielectric film 242 is etched and a final sidewall structure as shown in (c) can be obtained. Next, the primitive sidewall structure 244 is removed and an electrode material 245 is filled as shown in (d). By accomplishing planarization process such as chemical mechanical polishing (CMP), a structure as shown in (e) wherein the lower electrodes 245 are exposed and the width of the lower electrode 245 is reduced compared to the initial hole 240 diameter. Finally, patterned phase-change resistors 250 and upper electrodes 255 are formed as shown in (e).

Although being based on a similar technological concept with the structure of FIG. 3 in respect that the contact holes are narrowed by using the sidewalls, the structure shown in FIG. 4 has an advantage in that smaller contact area can be provided than the structure of FIG. 3 by increasing the thickness of the sidewall as a result of depositing the first dielectric film 242 together with the sacrificial layer 244. However, additional steps, such as depositing the first dielectric film, depositing the sacrificial layer, etching the sacrificial layer and etching the first dielectric film, are required so that the process is more complicate. Therefore, high productivity in manufacturing cannot be expected. In addition, the problem related to the voids formation in contact filling process as mentioned above still remains.

FIG. 5 shows yet another example of conventional technology for manufacturing phase-change memory disclosed in the U.S. laid-open patent No. 2002-0016054. The processing method comprises steps of: patterning a mask layer 311 on a conductive layer 310 formed on a substrate 305 as shown in (a); forming a tip-like structure as shown in (b) through wet etching; removing the residual mask layer 311; depositing a dielectric layer 335 as shown in (c) and performing planarization for the top surface 345 of the tips to be exposed as shown in (d); and finally forming patterned phase-change resistors 350 and upper electrodes 355 as shown in (e).

The conventional technology as explained with FIG. 5 is characterized in that tips formed by wet etching are used to reduce the contact area between the phase-change resistor and the electrode. However, it is extremely difficult to control wet etch process precisely. Therefore, it is very difficult to obtain process margin and uniform tip structure reproducibly for mass production. There can be device-to-device; wafer-to-wafer and batch-to-batch disparities in the width and height of the tips formed through the wet etch process. Such disparities may cause problems related to the reproducibility and reliability of the devices' characteristics, therefore limiting application of the conventional technology for mass production of the phase-change memory devices.

### SUMMARY OF THE INVENTION

Accordingly, the present invention has been made keeping in mind the above problems occurring in the prior art, and an object of the present invention is to provide a phase change memory device having a new structure which can be easily manufactured by mass-production with a high yield rate, therefore, reducing the cost of process and providing reliable device characteristics, and a manufacturing method thereof.

In order to accomplish the above object, the present invention provides a method for manufacturing a phase-change memory device comprising the steps of: (a) forming a lower electrode, at least a part of the lateral surface of the lower electrode being surrounded by a lower dielectric layer, at least a part of the top surface of the lower electrode being exposed; (b) forming a thin dielectric layer so that the exposed part of the top surface of the lower electrode and the top surface of the lower dielectric layer are covered; (c) forming a mask pattern on the thin dielectric layer; (d) forming a pore in the thin dielectric layer, having smaller area than the exposed part of the top surface of the lower electrode and aligned to the exposed part of the top surface of the lower electrode, by etching the thin dielectric layer with the mask pattern; (e) removing the mask pattern; and (f) depositing a phase-change material on the thin dielectric layer to fill the pore.

In accordance with another aspect of the present invention, the present invention provides a method for manufacturing a phase-change memory device comprising the steps of: (a) forming a lower electrode, at least a part of the lateral surface of the lower electrode being surrounded by a lower dielectric layer, at least a part of the top surface of the lower electrode being exposed; (b) forming a thin dielectric layer so that the exposed part of the top surface of the lower electrode and the top surface of the lower dielectric layer are covered; (c) forming a mask pattern on the thin dielectric layer; (d) forming a damaged spot in the thin dielectric layer, having smaller area than the exposed part of the top surface of the lower electrode and aligned to the exposed part of the top surface of the lower electrode, to provide a micro current path; (e) removing the mask pattern; and (f) depositing a phase-change material on the thin dielectric layer including the damaged spot.

Preferably, the step (a) comprises the steps of: forming a recessed part having a tapered sidewall in the lower dielectric layer; depositing the lower electrode material to fill the recessed part; and planarizing the lower electrode material so that the top surface of the part of the lower dielectric layer where the recessed part is not formed is exposed.

Preferably, the step (c) comprises the steps of: coating a polymeric resist film; and patterning on the polymeric resist film using an imprinting stamp having protrusions, the ends of which have width below than 1 micrometer.

Preferably, the step (d) comprises the step of exposing unmasked area on the thin dielectric layer to plasma, in order to form the damaged spot.

Preferably, the step (d) comprises the step of exposing unmasked area on the thin dielectric layer to a UV light, in order to form the damaged spot.

Preferably, the step (d) comprises the step of exposing unmasked area on the thin dielectric layer to an ion beam, in order to form the damaged spot.

In accordance with yet another aspect of the present invention, the present invention provides a method for manufacturing a phase-change memory device comprising the steps of: (a) forming a lower phase-change resistor, at least a part of the lateral surface of the phase-change resistor being surrounded by a lower dielectric layer, at least a part of the top surface of the lower phase-change resistor being exposed; (b) forming a thin dielectric layer so that the exposed part of the top surface of the lower phase-change resistor and the top surface of the lower dielectric layer are covered; (c) forming a mask pattern on the thin dielectric layer; (d) forming a pore in the thin dielectric layer, having smaller area than the exposed part of the top surface of the lower phase-change resistor and aligned to the exposed part of the top surface of the lower phase-change resistor, by etching the thin dielectric layer with the mask pattern; and (e) removing the mask pattern.

Preferably, the method further comprises the step of (f) depositing an electrode material on the thin dielectric layer to fill the pore.

Preferably, the method further comprises the step of (f) depositing a phase-change material on the thin dielectric layer to fill the pore and form an upper phase-change resistor.

In accordance with still yet another aspect of the present invention, the present invention provides a method for manufacturing a phase-change memory device comprising the steps of: (a) forming a lower phase-change resistor, at least a part of the lateral surface of the phase-change resistor being surrounded by a lower dielectric layer, at least a part of the top surface of the lower phase-change resistor being exposed; (b) forming a thin dielectric layer so that the exposed part of the top surface of the lower phase-change resistor and the top surface of the lower dielectric layer are covered; (c) forming a mask pattern on the thin dielectric layer; (d) forming a damaged spot in the thin dielectric layer, having smaller area than the exposed part of the top surface of the lower phase-change resistor and aligned to the exposed part of the top surface of the lower phase-change resistor, to provide a micro current path; and (e) removing the mask pattern.

Preferably, the method further comprises the step of (f) depositing an electrode material on the thin dielectric layer including the damaged spot.

Preferably, the method further comprises the step of (f) depositing a phase-change material on the thin dielectric layer including the damaged spot and form an upper phase-change resistor.

In accordance with still yet another aspect of the present invention, the present invention provides a phase-change memory device comprising: a lower dielectric layer; a lower electrode, at least a part of the lateral surface of the lower electrode being surrounded by the lower dielectric layer; a thin dielectric layer including a pore having smaller area than the top surface of the lower electrode, aligned to the top surface of the lower electrode and extending to the top surface of the lower electrode; and a phase-change resistor filling the pore and formed on the thin dielectric layer.

In accordance with still yet another aspect of the present invention, the present invention provides a phase-change memory device comprising: a lower dielectric layer; a lower electrode, at least a part of the lateral surface of the lower electrode being surrounded by the lower dielectric layer; a thin dielectric layer including a damaged spot having smaller area than the top surface of the lower electrode, aligned to the top surface of the lower electrode and providing a current path to the top surface of the lower electrode; and a phase-change resistor aligned to the damaged spot and formed on the thin dielectric layer.

Preferably, in the phase-change memory device, the lower electrode is filling a recessed part having a tapered sidewall in the lower dielectric layer so that the top surface area of the lower electrode is larger than the bottom surface area; and large lithographic margin is provided owing to the large top surface area.

In accordance with still yet another aspect of the present invention, the present invention provides a phase-change memory device comprising: a lower dielectric layer; a lower phase-change resistor, at least a part of the lateral surface of the lower phase-change resistor being surrounded by the lower dielectric layer; and a thin dielectric layer including a pore having smaller area than the top surface of the lower phase-change resistor, aligned to the top surface of the lower phase-change resistor and extending to the top surface of the lower phase-change resistor.

Preferably, the phase-change memory device further comprises an upper electrode filling the pore and formed on the thin dielectric layer.

Preferably, the phase-change memory device further comprises an upper phase-change resistor filling the pore and formed on the thin dielectric layer.

In accordance with still yet another aspect of the present invention, the present invention provides a phase-change memory device comprising: a lower dielectric layer; a lower phase-change resistor, at least a part of the lateral surface of the lower phase-change resistor being surrounded by the lower dielectric layer; and a thin dielectric layer including a damaged spot having smaller area than the top surface of the lower phase-change resistor, aligned to the top surface of the lower phase-change resistor and providing a current path to the top surface of the lower phase-change resistor.

Preferably, the phase-change memory device further comprises an upper electrode aligned to the damaged spot and formed on the thin dielectric layer.

Preferably, the phase-change memory device further comprises upper phase-change resistor aligned to the damaged spot and formed on the thin dielectric layer.

### BRIEF DESCRIPTION OF THE DRAWINGS

The above and other objects, features and advantages of the present invention will be more clearly understood from the following detailed description taken in conjunction with the accompanying drawings, in which:

FIG. 1 shows an example of a conventional structure of the phase-change memory device.

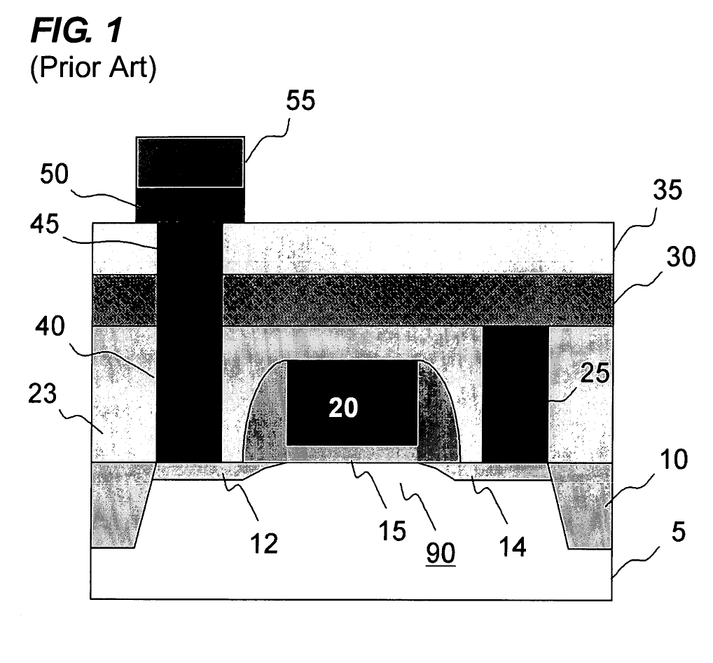

FIG. 2 shows the digital data storage mechanism using the phase-change materials' crystallization and amorphization in a phase-change memory device.

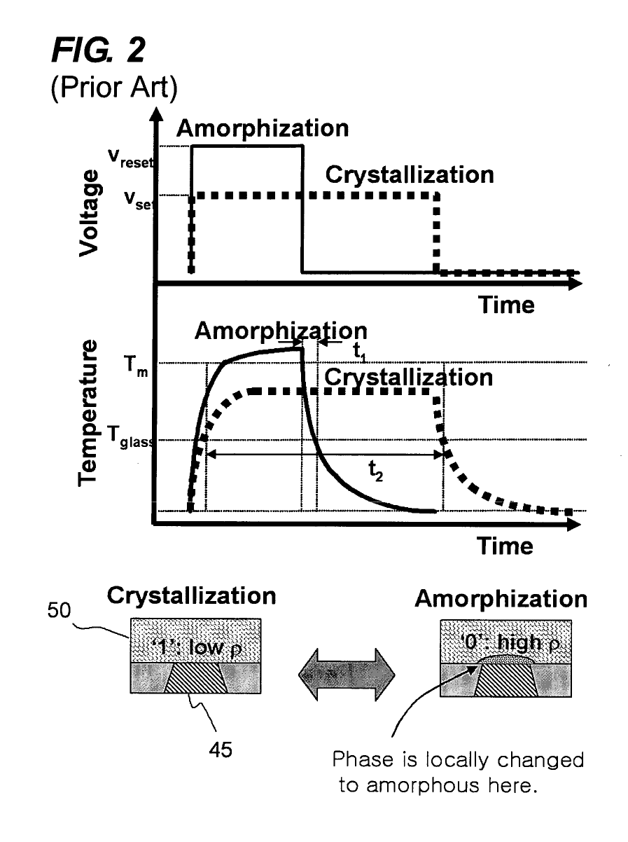

FIG. 3 shows an example of conventional structures of the phase-change memory devices and a processing method published in the U.S. patent Publication No. 6,420,725.

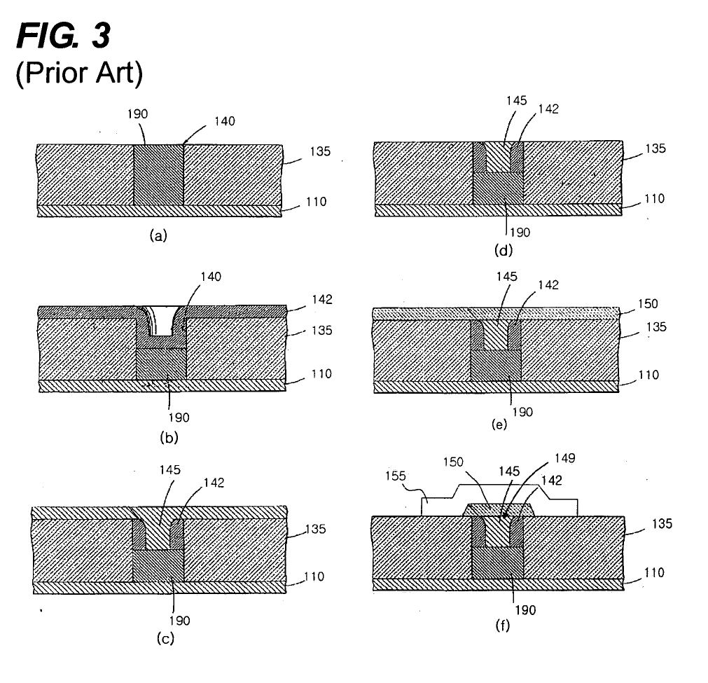

FIG. 4 shows another example of conventional phase-change memory device structure disclosed in the U.S. patent publication No. 6,337,266.

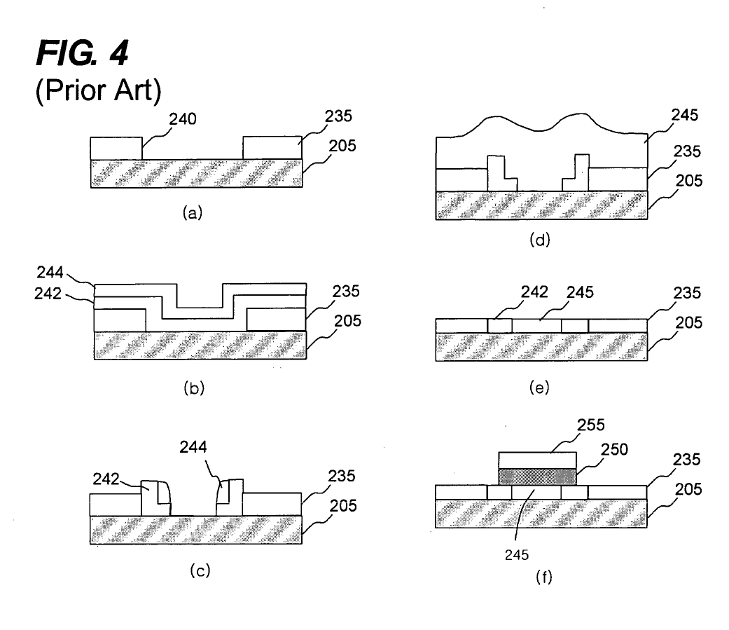

FIG. 5 shows yet another example of conventional technology for manufacturing phase-change memory disclosed in the U.S. laid-open patent No. 2002-0016054.

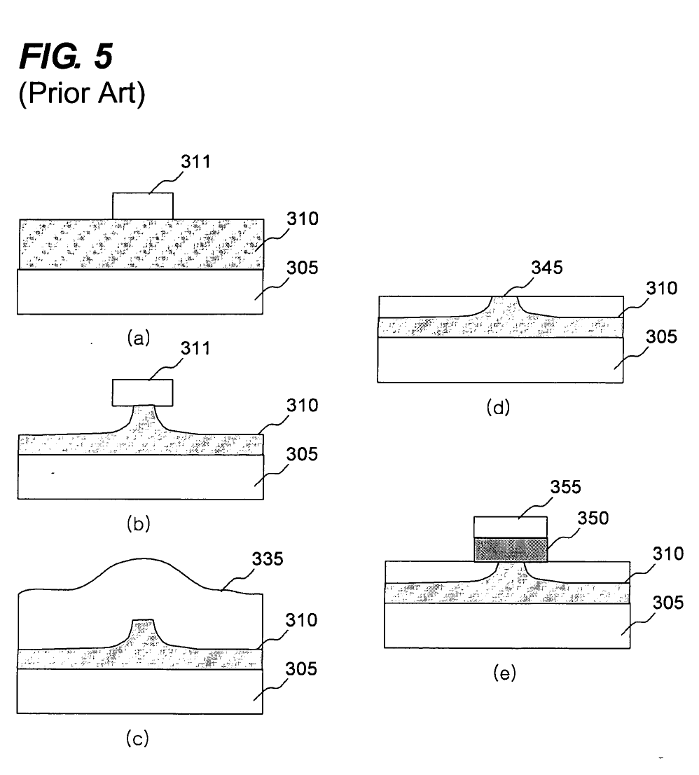

FIG. 6 shows an example of the phase-change memory device structure according to a preferred embodiment of the present invention.

FIG. 7 shows a structure of a phase-change memory device according to another preferred embodiment of the present invention.

FIG. 8 is a drawing for explaining the mechanism of forming a localized phase-changing region in the phase-change resistor by a localized current flow through a pore and a damaged spot.

FIG. 9 is a perspective view of the phase-change memory device according to the preferred embodiment of the present invention.

FIG. 10 is a drawing for explaining a preferred embodiment of the manufacturing method of the present invention.

FIG. 11 is a drawing for explaining the process flow in another preferred embodiment of the manufacturing method of the present invention.

FIG. 12 is a drawing for explaining the effect of the enhanced overlay margin by using the proposed structure.

FIG. 13 is a drawing for explaining yet another preferred embodiment of the manufacturing method of the present invention.

FIG. 14 shows the process steps for forming micro pores and phase-change resistors following the process step drawn in (f) of FIG. 13.

FIG. 15 shows an example of the device structure wherein the lower electrodes 845 have tapered sidewalls.

FIG. 16 shows yet another preferred embodiment of the phase-change memory device structure of the present invention.

FIG. 17 shows exemplified process steps for forming the device structure shown in FIG. 16.

### DESCRIPTION OF THE PREFERRED EMBODIMENTS

Reference now should be made to the drawings, in which the same reference numerals are used throughout the different drawings to designate the same or similar components.

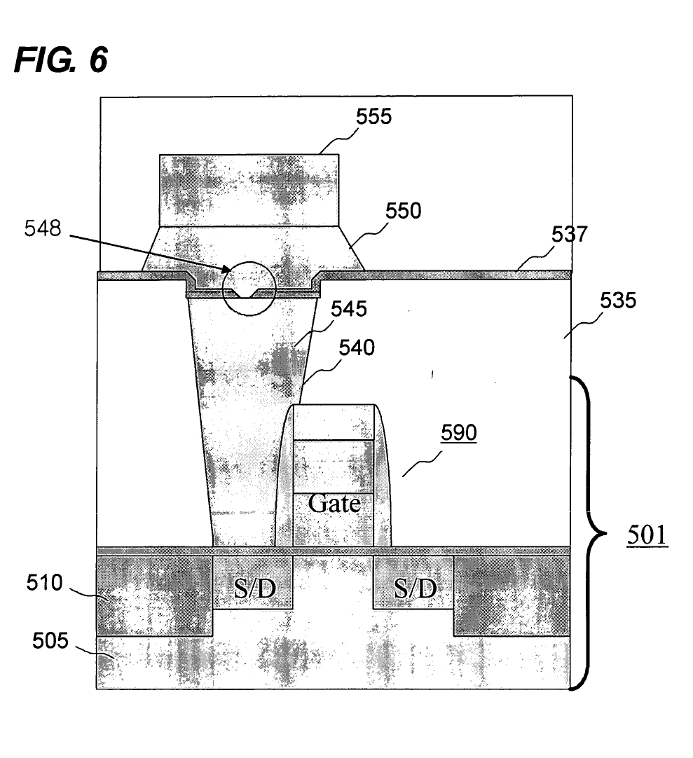

In FIG. 6, a phase-change memory device structure according to a preferred embodiment of the present invention is exemplified. An FET 590 is formed below a phase-change resistor 550 through a conventional CMOS process technology. In the structure, 1 memory cell includes 1 FET and 1 phase-change resistor. The structure below the phase-change resistor 550 can be variously modified in accordance with the specification which is required to meet in each of the detailed applications. For an example of the modifications, a LOCOS (Local Oxidation of Silicon) structure can replace the STI (Shallow Trench Isolation) structure 510 shown in FIG. 6 as a device isolation structure. For another example of the modifications, another type of switching device such as a BJT (Bipolar Junction Transistor) can replaced the FET 590 employed in the structure of FIG. 6. Therefore, the embodiment shown in FIG. 6 should be considered as an example.

In the preferred embodiment of FIG. 6, a lower dielectric layer 535 to insulate the CMOS structure and a contact hole 540 is formed in the lower dielectric layer 535. A lower electrode 545 is formed by filling the contact hole 540 with appropriate conducting materials. In addition, there is a thin dielectric layer 537 which cover the top surface of the lower electrode 545 and the top surface of the lower dielectric layer 535. The thin dielectric layer 537 isolates the phase-change resistor 550 from the lower electrode 545 so that they can contact electrically only through a micro pore 548 formed in the thin dielectric layer 537. The micro pore 548, which is formed through process steps explained in detail below, provides a local current path so that phase-changing can occur locally around the pore 548 in the phase-change resistor and therefore the phase-change memory device can be activated with even a small level of current. In addition, an upper electrode 555 is equipped on the phase-change resistor 550. The upper electrode 555 can be formed simultaneously with the phase-change resistor 550 through identical lithography and etch processes with one mask after deposition of the phase-change material layer and the electrode material layer. As a modification, the upper electrode 555 can be overlaid on the phase-change resistor 550, having a larger dimension than the phase-change resistor 550 and covering that. That modification can be chosen according to required device design parameters including overlay margin to obtain a predetermined integrity of the device and contact resistance.

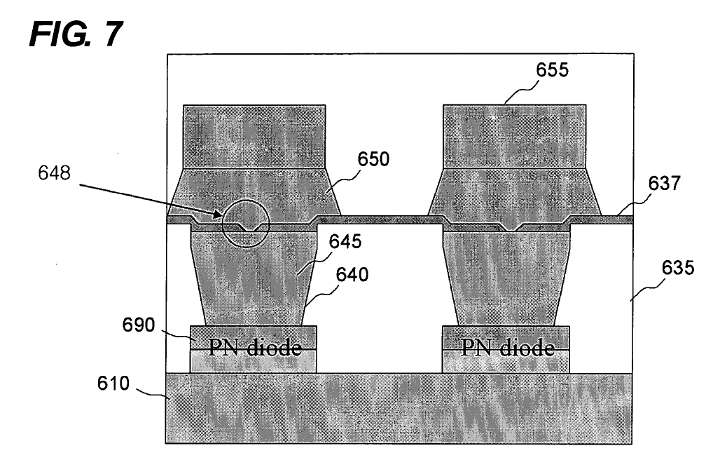

In FIG. 7, is shown a structure of a phase-change memory device according to another preferred embodiment of the present invention. In that structure, PN diodes 690 are formed below phase-change resistors 650 instead of the CMOS structure of FIG. 6. As mentioned above, that change can be considered as a modification of design by those skilled in the art. In the structure of FIG. 7, are there a lower dielectric layer 635, a contact hole 640 formed in the lower dielectric layer 635, a lower electrode 645 filling the contact hole 640, a thin dielectric layer 637 which cover the top surface of the lower electrode 645 and the top surface of the lower dielectric layer 635. The phase-change resistor 650 contacts to the lower electrode 645 electrically through a micro pore 648 formed in the thin dielectric layer 637, which provides a local current path.

In FIG. 6 and 7, the micro pores 548 and 648 provide local current paths so that phase-changing can occur locally around the pores 548 and 648 in the phase-change resistors therefore reducing operating voltage. Instead of the micro pores 548 and 648, local damaged spots or areas can be used for providing local current paths. Leakage current can flow through the local damaged spot formed in the thin dielectric layer. Method for forming the local damaged spot is explained in details below.

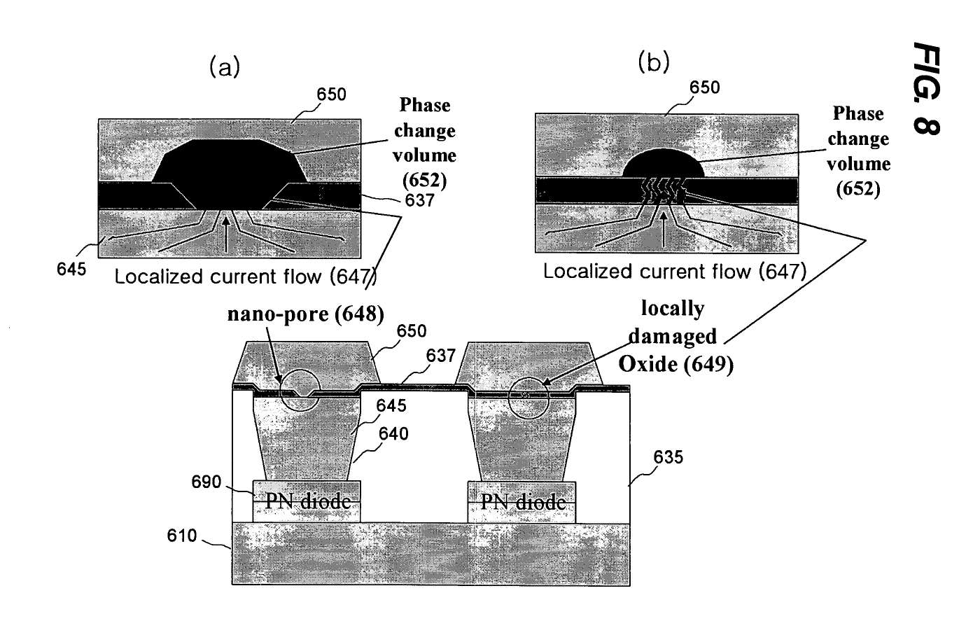

FIG. 8 is a drawing for explaining the mechanism of forming localized phase-changing region in the phase-change resistor by the localized current flow through the pore and the damaged spot. In the phase-change resistor 650, the phase-changing occurs in a region having a limited volume as shown in FIG. 8, because current density is high in the region as a result of the localization of current and heating of the phase-change material is performed proportionally to the square of the current density.

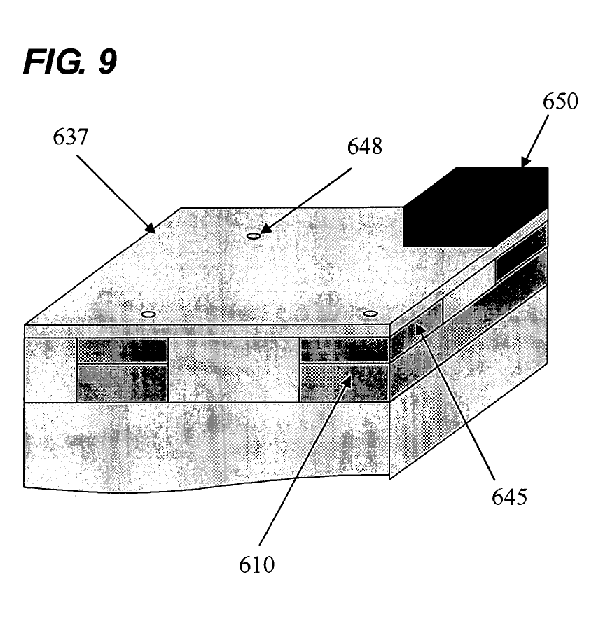

FIG. 9 is a perspective view of the phase-change memory device according to the preferred embodiment of the present invention. The lower electrode 645 is formed with a predetermined pattern so that each of the memory cells is discriminated. The thin dielectric layer 637 is deposited thereon and the pore or the damaged spot 648 is formed in the thin dielectric layer 637. After that, the phase-change resistor 650 is deposited and patterned. It can be appreciated that the present invention provides another advantageous effect considering overlay margin in a lithographic process for patterning the pore or the damaged spot above the patterned lower electrode 645. By employing the device structure of the present invention, the overlay margin can be improved because the dimension of the pore and the damaged spot is much smaller than the top area of the lower electrode 645. The overlay margin in a lithographic process for patterning the phase-change resistor 650 over the pore or the damaged spot can also be improved therefore contributing the yield and the productivity of manufacturing process.

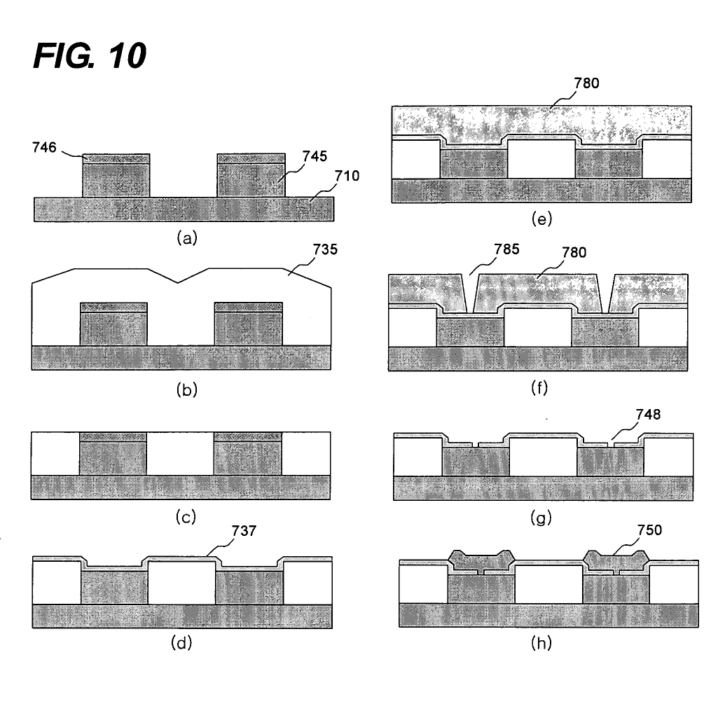

FIG. 10 is a drawing for explaining a preferred embodiment of the manufacturing method of the present invention. A lower electrode 745 is formed on a substrate 710 through a lithographic process with a mask pattern as shown in (a). The substrate 710 can be glass, sapphire, quartz, ceramic, silicon wafer or others including lower structures already formed thereon through precedent processes. When the lower electrode 745 is structured, a dielectric film 735 is deposited as shown in (b). In case that a mask 746 for patterning the lower electrode 745 is a photo-resist film, it has to be removed before depositing the dielectric film 735. But, if the mask 746 is a hard mask such as silicon dioxide or silicon nitride film, then it is not necessary to be removed and the dielectric film 735 can be directly deposited on top of the hard mask 746 as shown in (b) . In some cases, the hard mask 746 can be used as an etch-stopper layer in a CMP process.

After that, a planarization is fulfilled by using a CMP, an etch-back or other processes as illustrated in (c). However, it is not essential to fulfill the planarization and in case that flatness is not required in a succeeding process (especially a lithographic process), the planarization process can be omitted. In that case, BPSG, SOG or other dielectric materials can be used to provide a surface having an acceptable degree of flatness.

As drawn in (d), the top surface of the lower electrode 745 and the top surface of the lower dielectric layer 737 are covered with a thin dielectric layer 737 after removing the mask 746. Then, a mask material film 780 is coated and a patterning process is performed as shown in (e). For the mask material film 780, a photo resist layer or a polymer layer can be used. The mask material can be chosen according to the lithography process. To obtain the micro pore or the damaged spot which has much smaller dimension than the top surface of the lower electrode, the exposed bottom area in the pattern should be much smaller than the top surface area of lower electrode as shown in (f). Therefore, e-beam lithography or nano-imprinting lithography which will be further explained below is ideal for obtaining the small sized pattern as mentioned above.

The nano-imprinting lithography is considered as a remarkable technology which can overcome the limitation of photo lithographic process and resolve productivity problem and economic issue which can not be overcome in other technologies such as e-beam lithography, X-ray lithography, proximal probe lithography and dip pen lithography to obtain ultra micro patterns less than 70 nm. The nano-imprinting lithography can provide very faster processing speed compared to the e-beam lithography process, therefore, it is ideal for being used in mass production of devices which have very small structures embodied by the ultra micro patterning. Also it provides high productivity and can overcome the limitation of the conventional photo lithography, therefore, receiving a spotlight as the most complete lithography process.

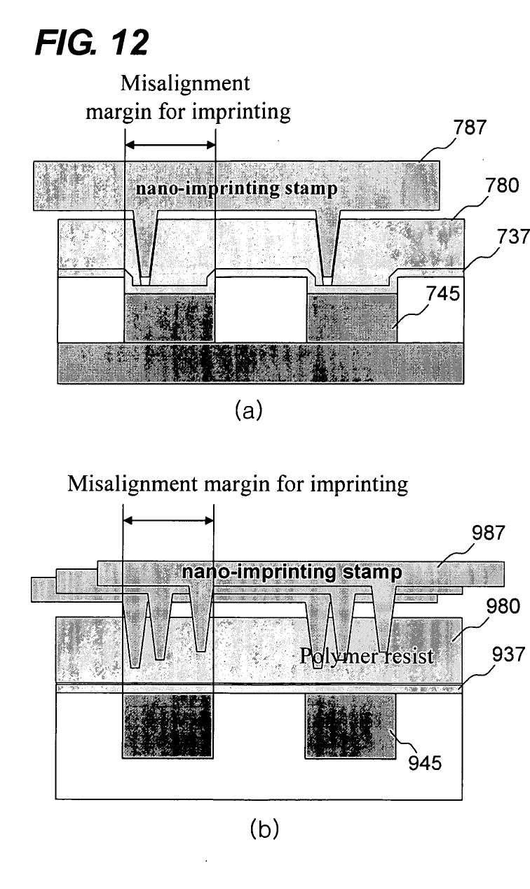

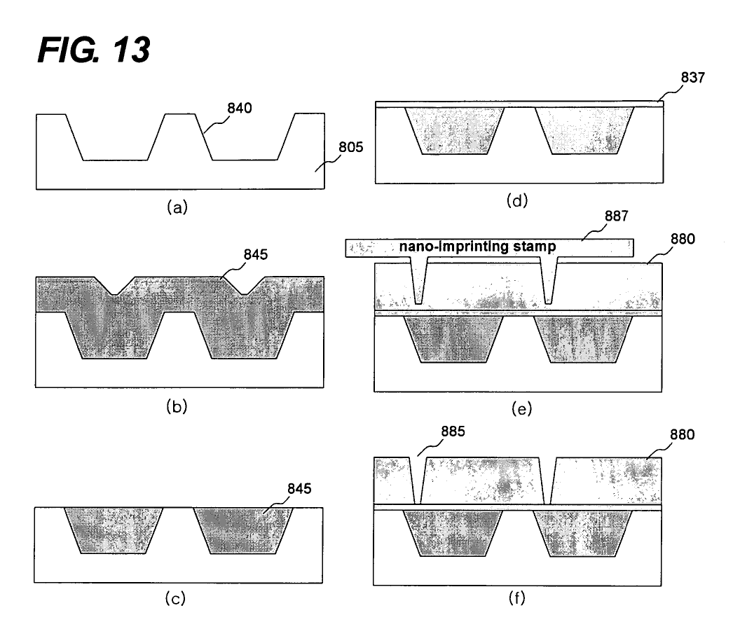

To embody the proposed structure of the phase-change memory device in the present invention, it is preferred to use the nano-imprinting lithographic technology. As shown in FIGS. 12 and 13, to embody the micro pore or the damaged spot, ultra micro patterns are formed in the polymeric film 780 (for example, PMMA film) by using an imprinting stamp 787.

The patterns formed on the nano-imprinting stamp 787 are nano-sized, especially at the end tips of the patterns. Preferably, the nano-imprinting stamp 787 is made of a transparent material prepared by using a silicon nano-casting method disclosed in the Korean Patent application No. 2003-62050 by the same inventor with the present invention. The method for preparing the nano-imprinting stamp by the nano-casting comprises the steps of: forming desired patterns in a mask layer on a silicon wafer by using, for example, the e-beam lithography process, wherein the patterns are negative patterns of the final patterns which will be formed on the nano-imprinting stamp; etching the silicon wafer to engrave the silicon wafer with the patterns; filling the engraved patterns on the silicon wafer by depositing a desired material such as silicon dioxide and aluminum oxide; planarizing the top surface of the deposited layer; bonding a handling wafer to the top surface of the planarized layer and removing the silicon wafer by a selective etching process. The nano-casting technology proposed by the inventor of the present invention utilizes excellent micro processing capabilities of silicon and therefore provides easy and reliable method for making the nano-imprinting stamp.

In FIG. 10, (e) shows the etched thin dielectric film with the patterns formed by using the nano-imprinting lithography. As a result of the etching process, micro pores 748 are formed in the thin dielectric layer. Phase-change material is deposited to fill the micro pores 748 and patterned through lithography and etch processes as shown in (h) of FIG. 10.

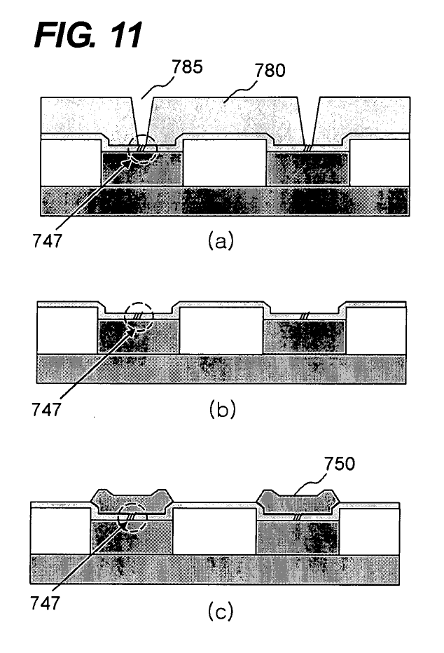

In FIG. 11, process flow in another preferred embodiment of the manufacturing method of the present invention is shown. The preferred embodiment is characterized in that damaged spots 747 are formed by exposing small parts of the top surface of the thin dielectric layer to plasma or ion-beam. A variety of plasmas formed discharging oxygen, argon or other gases can be used for the damaging process. In addition, a variety of power supplying methods for discharging such as microwave type, RIE type and ICP type can be used. The damaging process can also be fulfilled simultaneously with a photo resist stripping process in a single tool using the oxygen plasma. In that case, appropriate gas can be chosen to avoid etching of the thin dielectric film 737.

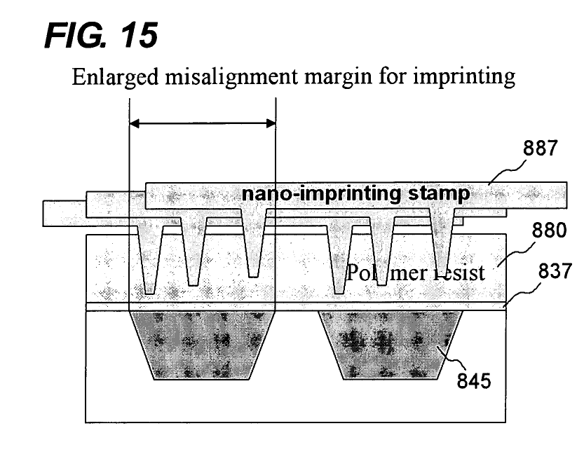

As explained above, the structure of the phase-change memory device proposed in the present invention can provide a very advantageous effect in consideration of the overlay margin of the lithographic processes. FIG. 12 is a drawing for explaining the effect of the enhanced overlay margin by using the proposed structure. As shown in FIG. 12, the proposed structure employing the micro pores provides large overlay margin even in case that the lower electrodes 945 have vertical sidewalls thus providing reliability of manufacturing processes and enhancing productivity. In case that the lower electrodes 845 have tapered sidewalls as shown in FIG. 15, the overlay margin can be enhanced more because the top surface area of the lower electrode 845 is larger. Also in the structure of FIG. 15, the recessed regions having tapered sidewalls in the lower dielectric layer can be easily filled with metallic materials avoiding voids and seems, and the lower electrodes having good electrical properties can be obtained.

Yet another preferred embodiment of the manufacturing method of the present invention is explained in FIG. 13. The preferred embodiment is characterized in that recessed regions having tapered sidewalls 840 are formed in a lower dielectric layer 805. The recessed regions are trenches or contact holes formed through patterning and etching the lower dielectric layer 805. To form the tapered sidewalls a variety of known processing methods, for example by just controlling process parameters in the etching process, can be used. In FIG. 13, (b) shows a result of filling the contact holes or the trenches having tapered sidewalls with a lower electrode forming material 845. In (c), a planarized surface obtained through a planarization process such as the CMP is drawn. After that, a thin dielectric layer 837 is deposited as shown in (d) and a nano-imprinting lithographic process is performed as shown in (e) and (f).

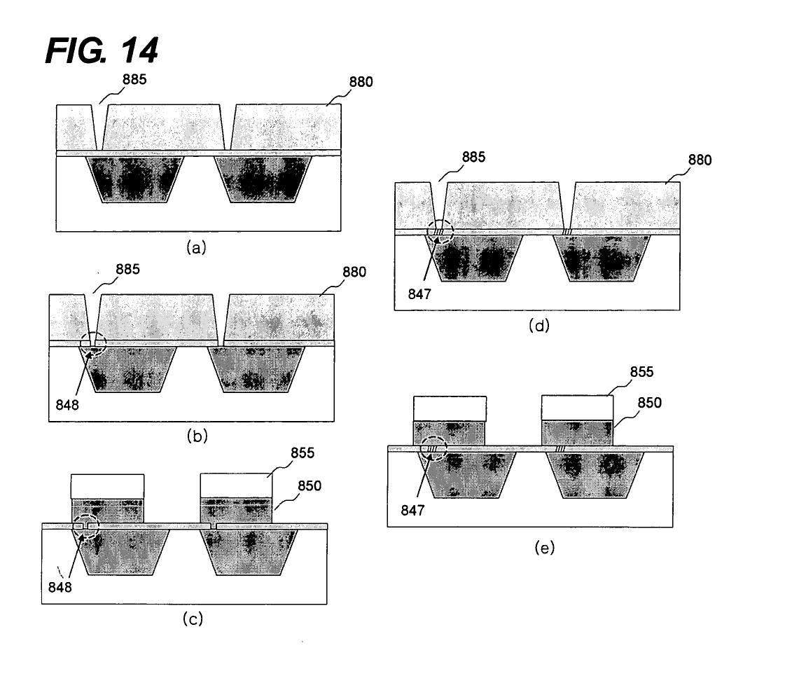

In FIG. 14, the process steps for forming micro pores 848 and phase-change resistors 850 following the process step drawn in (f) of FIG. 13. The (a), (b) and (c) of FIG. 14 show the steps for forming the micro pores 848 which can provide the local current paths. The (d) and (e) of FIG. 14 show the alternative processing steps for forming local damaged spots 847 instead of the micro pores 848 are described.

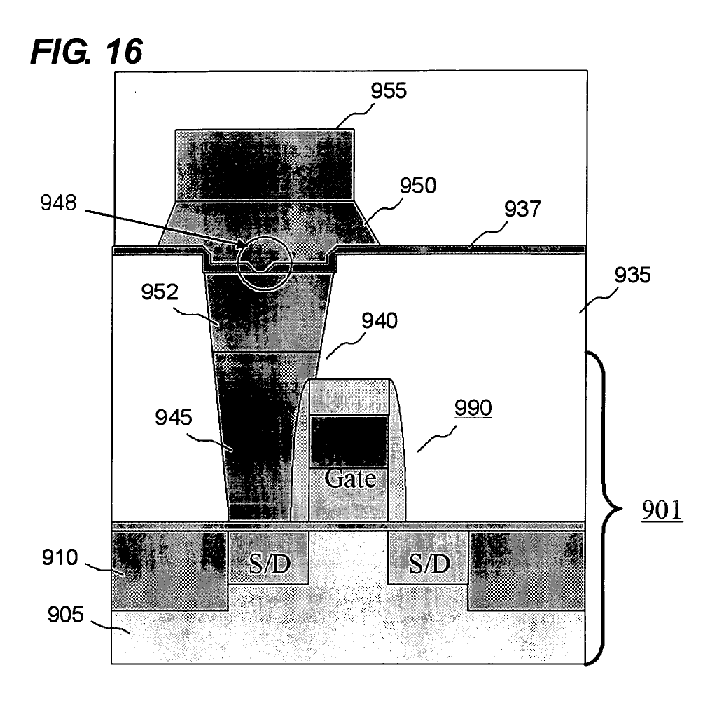

In FIG. 16, yet another preferred embodiment of the phase-change memory device structure of the present invention is shown. In that structure, a lower phase-change resistor 952 is formed above a lower electrode 945 and below a thin dielectric layer 937 where a micro pore 948 is formed. On the thin dielectric layer 937, an upper phase-change resistor 950 and an upper electrode 955 is patterned. The micro pore 948 (or local damaged spot) localizes current flow and phase-changing region within the phase-change resistors 952 and 950. As a modification, another structure where the upper phase-change resistor 950 is omitted can be easily conceived by those skilled in the art.

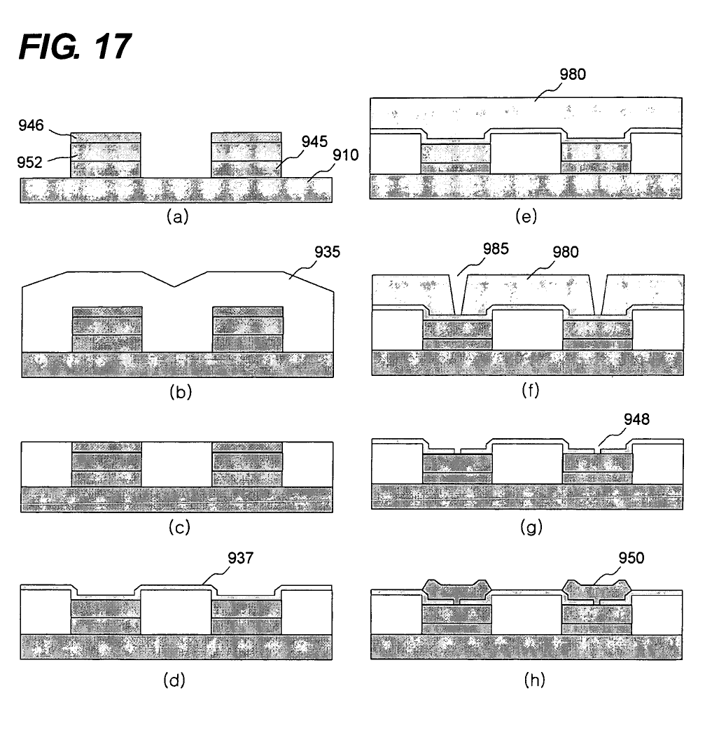

In FIG. 17, the process steps for forming the device structure shown in FIG. 16 are exemplified. The structure can be embodied through similar process steps with those already described in FIG. 10 except that a lower phase-change resistor 952 is deposited on and patterned with a lower electrode 945 as shown in (a) of FIG. 17.

By employing the present invention, the phase-change memory device, which is operated with very low power, can be obtained. As the volume where the current density is high in the phase-change resistor decreases, the required level of currents during a set and a reset operation of the phase-change memory device can be reduced and switching speed can be improved. Thus, by employing the present invention, reliability of the device can be significantly enhanced.

To summarize the advantageous effects of the present invention, it is possible by using the present invention to provide a phase change memory device having a new structure which can be easily manufactured by mass-production with a high yield rate, therefore, reducing the cost of process and providing reliable device characteristics, and a manufacturing method thereof.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A method for manufacturing a phase-change memory device comprising the steps of:
(a) forming a lower electrode, at least a part of the lateral surface of the lower electrode being surrounded by a lower dielectric layer, at least a part of the top surface of the lower electrode being exposed;
(b) forming a thin dielectric layer so that the exposed part of the top surface of the lower electrode and the top surface of the lower dielectric layer are covered;
(c) forming a mask pattern on the thin dielectric layer;
(d) forming a pore in the thin dielectric layer, having smaller area than the exposed part of the top surface of the lower electrode and aligned to the exposed part of the top surface of the lower electrode, by etching the thin dielectric layer with the mask pattern;
(e) removing the mask pattern; and
(f) depositing a phase-change material on the thin dielectric layer to fill the pore.

2. The method as set forth in claim 1, wherein the step (a) comprises the steps of:
forming a recessed part having a tapered sidewall in the lower dielectric layer;
depositing the lower electrode material to fill the recessed part; and
planarizing the lower electrode material so that the top surface of the part of the lower dielectric layer where the recessed part is not formed is exposed.

3. The method as set forth in claim 1, wherein the step (c) comprises the steps of:
coating a polymeric resist film; and
patterning on the polymeric resist film using an imprinting stamp having protrusions, the ends of which have width below than 1 micrometer.

4. A method for manufacturing a phase-change memory device comprising the steps of:
(a) forming a lower electrode, at least a part of the lateral surface of the lower electrode being surrounded by a lower dielectric layer, at least a part of the top surface of the lower electrode being exposed;
(b) forming a thin dielectric layer so that the exposed part of the top surface of the lower electrode and the top surface of the lower dielectric layer are covered;
(c) forming a mask pattern on the thin dielectric layer;
(d) forming a damaged spot in the thin dielectric layer, having smaller area than the exposed part of the top surface of the lower electrode and aligned to the exposed part of the top surface of the lower electrode, to provide a micro current path;
(e) removing the mask pattern; and
(f) depositing a phase-change material on the thin dielectric layer including the damaged spot.

5. The method as set forth in claim 4, wherein the step (a) comprises the steps of:
forming a recessed part having a tapered sidewall in the lower dielectric layer;
depositing the lower electrode material to fill the recessed part; and
planarizing the lower electrode material so that the top surface of the part of the lower dielectric layer where the recessed part is not formed is exposed.

6. The method as set forth in claim 4, wherein the step (c) comprises the steps of:
coating a polymeric resist film; and
patterning on the polymeric resist film using an imprinting stamp having protrusions, the ends of which have width below than 1 micrometer.

7. The method as set forth in claim 4, wherein the step (d) comprises the step of:
exposing unmasked area on the thin dielectric layer to a plasma, in order to form the damaged spot.

8. The method as set forth in claim 4, wherein the step (d) comprises the step of:
exposing unmasked area on the thin dielectric layer to a UV light, in order to form the damaged spot.

9. The method as set forth in claim 4, wherein the step (d) comprises the step of:
exposing unmasked area on the thin dielectric layer to an ion beam, in order to form the damaged spot.

10. A method for manufacturing a phase-change memory device comprising the steps of:
(a) forming a lower phase-change resistor, at least a part of the lateral surface of the phase-change resistor being surrounded by a lower dielectric layer, at least a part of the top surface of the lower phase-change resistor being exposed;
(b) forming a thin dielectric layer so that the exposed part of the top surface of the lower phase-change resistor and the top surface of the lower dielectric layer are covered;
(c) forming a mask pattern on the thin dielectric layer;
(d) forming a pore in the thin dielectric layer, having smaller area than the exposed part of the top surface of the lower phase-change resistor and aligned to the exposed part of the top surface of the lower phase-change resistor, by etching the thin dielectric layer with the mask pattern; and
(e) removing the mask pattern.

11. The method as set forth in claim 10, further comprising the step of:
(f) depositing an electrode material on the thin dielectric layer to fill the pore.

12. The method as set forth in claim 10, further comprising the step of:
(f) depositing a phase-change material on the thin dielectric layer to fill the pore and form an upper phase-change resistor.

13. A method for manufacturing a phase-change memory device comprising the steps of:
(a) forming a lower phase-change resistor, at least a part of the lateral surface of the phase-change resistor being surrounded by a lower dielectric layer, at least a part of the top surface of the lower phase-change resistor being exposed;
(b) forming a thin dielectric layer so that the exposed part of the top surface of the lower phase-change resistor and the top surface of the lower dielectric layer are covered;
(c) forming a mask pattern on the thin dielectric layer;
(d) forming a damaged spot in the thin dielectric layer, having smaller area than the exposed part of the top surface of the lower phase-change resistor and aligned to the exposed part of the top surface of the lower phase-change resistor, to provide a micro current path; and
(e) removing the mask pattern.

14. The method as set forth in claim 13, further comprising the step of:
(f) depositing an electrode material on the thin dielectric layer including the damaged spot.

15. The method as set forth in claim 13, further comprising the step of:
(f) depositing a phase-change material on the thin dielectric layer including the damaged spot and form an upper phase-change resistor.

16. A phase-change memory device comprising:
(a) a lower dielectric layer;
(b) a lower electrode, at least a part of the lateral surface of the lower electrode being surrounded by the lower dielectric layer;
(c) a thin dielectric layer including a pore having smaller area than the top surface of the lower electrode, aligned to the top surface of the lower electrode and extending to the top surface of the lower electrode; and
(d) a phase-change resistor filling the pore and formed on the thin dielectric layer.

17. The phase-change memory device as set forth in claim 16, wherein the lower electrode is filling a recessed part having a tapered sidewall in the lower dielectric layer so that the top surface area of the lower electrode is larger than the bottom surface area; and
wherein large lithographic margin is provided owing to the large top surface area.

18. A phase-change memory device comprising:
(a) a lower dielectric layer;
(b) a lower electrode, at least a part of the lateral surface of the lower electrode being surrounded by the lower dielectric layer;
(c) a thin dielectric layer including a damaged spot having smaller area than the top surface of the lower electrode, aligned to the top surface of the lower electrode and providing a current path to the top surface of the lower electrode; and
(d) a phase-change resistor aligned to the damaged spot and formed on the thin dielectric layer.

19. The phase-change memory device as set forth in claim 18, wherein the lower electrode is filling a recessed part having a tapered sidewall in the lower dielectric layer so that the top surface area of the lower electrode is larger than the bottom surface area; and
wherein large lithographic margin is provided owing to the large top surface area.

20. A phase-change memory device comprising:
(a) a lower dielectric layer;
(b) a lower phase-change resistor, at least a part of the lateral surface of the lower phase-change resistor being surrounded by the lower dielectric layer; and
(c) a thin dielectric layer including a pore having smaller area than the top surface of the lower phase-change resistor, aligned to the top surface of the lower phase-change resistor and extending to the top surface of the lower phase-change resistor.

21. The phase-change memory device as set forth in claim 20, further comprising:
(d) an upper electrode filling the pore and formed on the thin dielectric layer.

22. The phase-change memory device as set forth in claim 20, further comprising:
(d) an upper phase-change resistor filling the pore and formed on the thin dielectric layer.

23. A phase-change memory device comprising:
(a) a lower dielectric layer;
(b) a lower phase-change resistor, at least a part of the lateral surface of the lower phase-change resistor being surrounded by the lower dielectric layer; and
(c) a thin dielectric layer including a damaged spot having smaller area than the top surface of the lower phase-change resistor, aligned to the top surface of the lower phase-change resistor and providing a current path to the top surface of the lower phase-change resistor.

24. The phase-change memory device as set forth in claim 23, further comprising:
(d) an upper electrode aligned to the damaged spot and formed on the thin dielectric layer.

25. The phase-change memory device as set forth in claim 23, further comprising:
(d) an upper phase-change resistor aligned to the damaged spot and formed on the thin dielectric layer.
